(19) United States
(12) Patent Application Publication
(10) Pub. No.: US 2008/0089124 A1
(43) Pub. Date: Apr. 17, 2008

(54) REMOVABLE DATA STORAGE DEVICE AND METHOD

(76) Inventor: Quang V.T. Nguyen, Toronto (CA)

Correspondence Address: BERESKIN AND PARR, 40 KING STREET WEST, BOX 401, TORONTO, ON, M5H 3Y2, CA

(21) Appl. No.: 11/862,780

(22) Filed: Sep. 27, 2007

Related U.S. Application Data
(60) Provisional application No. 60/827,100, filed on Sep. 27, 2006.

(51) Int. Cl. G11C 11/34

(52) U.S. Cl. 365/185.04; 360/99.06

(57) ABSTRACT

Applicant's teachings relate to a removable data storage device and method. Various embodiments of applicant's teachings show a removable data storage device comprising an external connector to removably connect the data storage device to a computing device, a memory device mounted on a first printed circuit board, a flexible connector for providing an electrical connection between the memory device and the external connector, a housing for enclosing the memory device, and a plurality of bumpers for physically isolating the memory device and printed circuit board from the housing, each bumper shaped to securely receive at least one edge of the printed circuit board.

This application claims the benefit of U.S. Provisional Application No. 60/827,100, filed Sep. 25, 2007, the entire contents of which is hereby incorporated by reference.

The section headings used herein are for organizational purposes only and are not to be construed as limiting the subject matter described in any way.

### FIELD

Applicant's teachings are related to a removable data storage device and method.

### SUMMARY

Applicant's teachings relate to a removable data storage device and method. Various embodiments of applicant's teachings show a removable data storage device comprising an external connector to removably connect the data storage device to a computing device, a memory device mounted on a first printed circuit board, a flexible connector for providing an electrical connection between the memory device and the external connector, a housing for enclosing the memory device, and a plurality of bumpers for physically isolating the memory device and printed circuit board from the housing, each bumper shaped to securely receive at least one edge of the printed circuit board.

In some embodiments of applicant's teachings the memory device is electrically coupled to the first printed circuit board. A first end of the flexible connector is electrically coupled to the first printed circuit board to provide the electrical connection between the memory device and the external connector. In some embodiments of applicant's teachings the memory device is rigidly mounted on the printed circuit board.

In some embodiments of applicant's teachings the removable data storage device includes a second printed circuit board, the second printed circuit board mounted in the housing, the external connector is mounted on and electrically coupled to the second printed circuit board, and a second end of the flexible connector is coupled to the second printed circuit board in order to provide the electrical connection between the memory device and the external connector.

The removable data storage device can further include a plurality of tabs affixed to the housing, so that each tab abuts a bumper in order to prevent movement of the bumper. In some embodiments of applicant's teachings each bumper is made of a shock absorbing material, for example, but not limited to, rubber.

The external connector can be, for example, but not limited to, a multiple point contact connector or a multiple-pin contact connector.

According to some embodiments of applicant's teachings power is provided to the memory device through the external connector.

Moreover, according to some embodiments of applicant's teachings the printed circuit board has a rectangular shape and the plurality of bumpers include four corner bumpers, each corner bumper shaped to receive a corner of the printed circuit board.

In accordance with various embodiments of applicants teachings a method of protecting a memory device form shocks and vibrations is disclosed. The method comprises:
(a) providing an external connector for coupling the data storage device to a computing device;
(b) providing a flexible connector for providing an electrical connection between the memory device and the external connector;
(c) mounting the memory device on a first printed circuit board;
(d) providing a housing for enclosing the memory device; and
(e) providing a plurality of bumpers for physically isolating the memory device and printed circuit board from the housing, each bumper shaped to securely receive at least one edge of the printed circuit board.

Moreover, according to some embodiments of applicant's teachings, the step (b) of the method further comprises electrically coupling the flexible connector to the first printed circuit board to provide the electrical connection between the memory device and the external connector.

Moreover, in accordance with some embodiments of applicant's teachings step (c) comprises rigidly mounting the memory device on the printed circuit board.

Further, the method can comprise in some embodiments of applicant's teachings:
(g) providing a second printed circuit board;
(h) mounting the second circuit board to the housing; and
(i) mounting and electrically coupling the external connector to the second printed circuit board;
so that step (b) further comprises electrically coupling the flexible connector to the second printed circuit board in order to provide the electrical connection between the memory device and the external connector.

In accordance with various embodiments of applicant's teachings the method further comprises providing a plurality of tabs affixed to the housing, so that each tab abuts a bumper in order to prevent movement of the bumper. Each bumper is made of a shock absorbing material such as, for example, but not limited to, rubber.

The external connector can be, for purposes of example of applicant's teachings, but not limited to, a multiple point contact connector, or a multiple-pin contact connector.

The method can further comprise in some embodiments of applicant's teachings providing power to the memory device through the external connector.

Further, according to some embodiments of applicant's teachings, the printed circuit board of the method has a rectangular shape and the plurality of bumpers can comprise four corner bumpers, each corner bumper shaped to receive a corner of the printed circuit board.

### BRIEF DESCRIPTION OF THE DRAWINGS

The skilled person in the art will understand that the drawings, described below, are for illustration purposes only. The drawings are not intended to limit the scope of the applicant's teachings in any way.

FIG. 1A is a perspective view of a removable data storage device according to some embodiment's of applicant's teachings;

FIG. 1B is a perspective view of the base and the internal components of the removable data storage device of FIG. 1A;

FIG. 1C is a rear view of the base and the internal components of the removable data storage device of FIG. 1A;

FIG. 1D is a perspective view of the base and the internal components of the removable data storage device of FIG. 1A, with the second PCB board partially removed;

FIG. 1E is a perspective view of the cover of data storage device of FIG. 1A;

FIG. 2A is a side view of a bumper of FIG. 1B;

FIG. 2B is a perspective view of the bumper of FIG. 2A.

### DETAILED DESCRIPTION

In various embodiments, applicant's teachings are related to an apparatus and method for providing a robust portable and removable data storage device. Further, in other embodiments, applicant's teachings are related to an apparatus and method for protecting a memory device from damage that may be caused by external forces applied to the removable data storage device. Moreover, in various embodiments, applicant's teachings are related to an apparatus and method for protecting the data stored on a memory device from damage that may be caused by external forces applied to the removable data storage device.

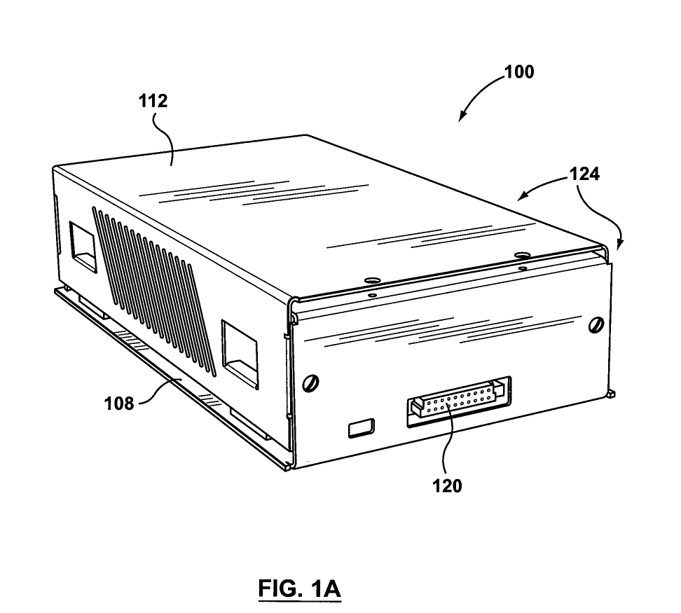

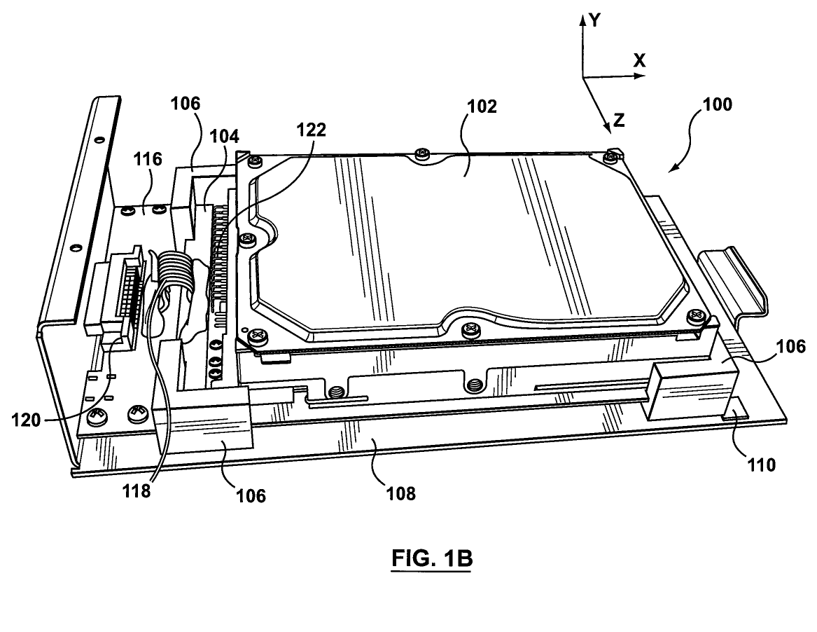

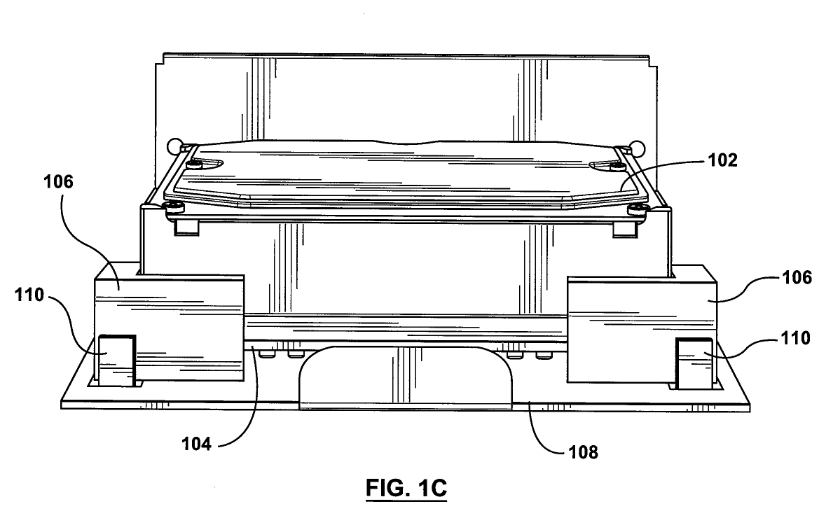

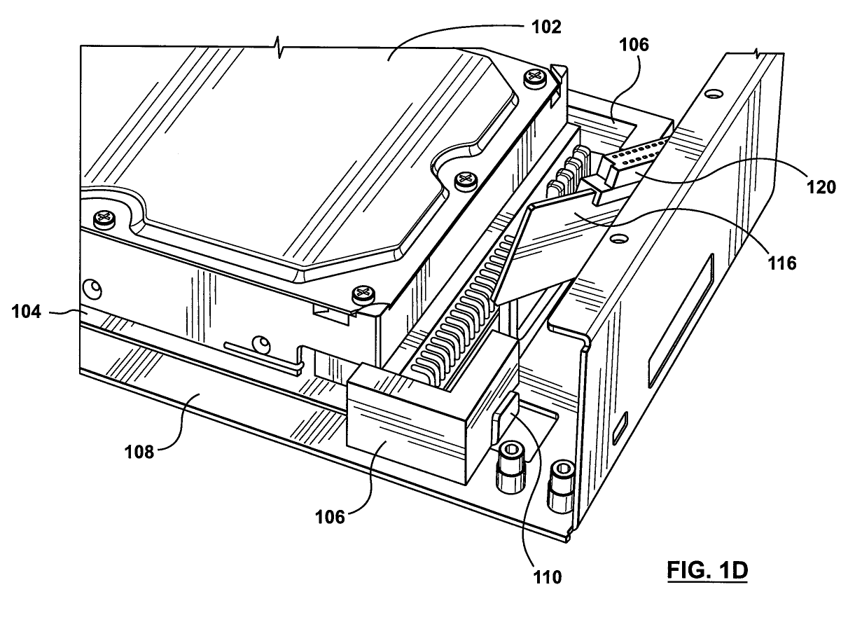

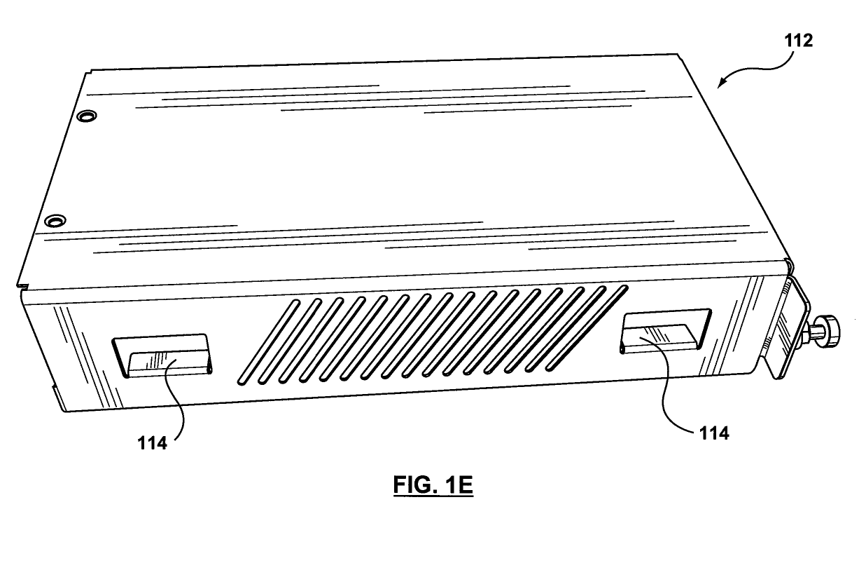

Reference is now made to FIGS. 1A to 1E, which illustrate the components of a removable data storage device 100, according to various embodiments of applicant's teachings. Removable data storage device 100 comprises a memory device 102, a first printed circuit board (PCB) board 104 upon which memory device is mounted, bumpers 106, a base 108, a first plurality of tabs 110, a cover 112, a second plurality of tabs 114, a second PCB board 116, a flexible connector 118, an external connector 120, and a connector 122 for connecting the memory device 102 to PCB board 104. Cover 108 and base 126 forms an external housing 124 for removable data storage device 100.

Although the embodiments illustrated in FIGS. 1A to 1E, make use of two PCB boards, it is not intended to exclude embodiments in which a single PCB board is used.

In FIG. 1D, second PCB board 116 is partially removed in order to better show a portion of the plurality of tabs 110. As can be seen from FIGS. 1B to 1D, in various embodiments, the first plurality of tabs 110, exist on either side of PCB board 104 in the direction X. The plurality of tabs 110 will be discussed in greater detail below.

Memory device 102 can be rigidly mounted on first PCB board 104. Memory device 102 can be any appropriate device used for storing information including, but not limited to, electromechanical memory devices. In various embodiments illustrated in FIGS. 1A to 1E, memory device 102 is a hard disk drive (HDD).

In some embodiments first PCB board 104 can also include a heating element, one or more conditions sensors, and related control circuitry (not shown). Condition sensors can be, for example, but not limited to, temperature sensors and humidity sensors. The heating element can be, for example, but not limited to, a copper trace on PCB board 104. The heating element as well as memory device 102 may be operated according to the conditions sensed by the condition sensors. For example, if one of the condition sensors is a temperature sensor and it senses a temperature below a preselected threshold, then the heating element may be activated. In addition, if one of the condition sensors senses a condition outside the acceptable operable conditions of memory device 102, then the source of power for memory device 102 may be disconnected from memory device 102.

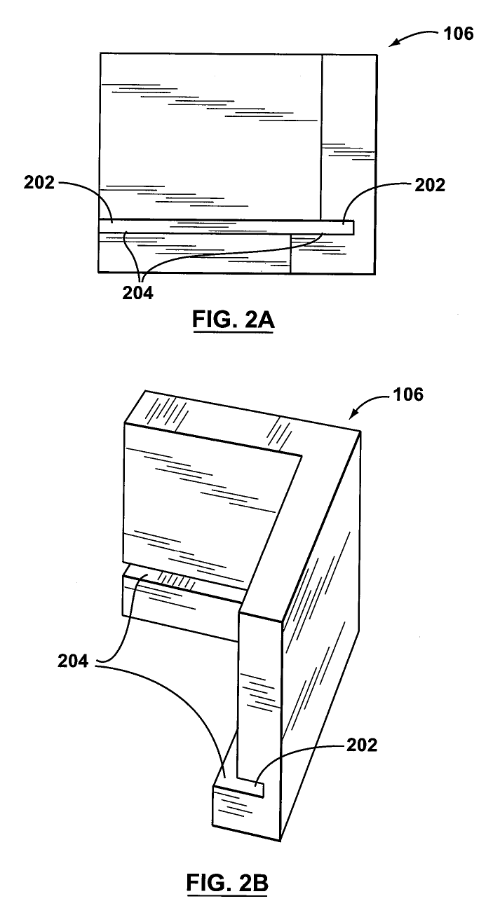

Reference is now made to FIGS. 2A and 2B, which illustrate a bumper 106 of FIG. 1B. Bumpers 106 have a slot 202 for receiving one or more edges of PCB board 104. In some embodiments, at least some of bumpers 106 are corner bumpers that receive a corner of PCB board 104. In some embodiments, bumpers 106 do not come in contact with memory device 102. Bumpers 106 can have a protrusion 204 for extending beneath PCB board 104. Bumpers 106 can be made of any appropriate material that absorbs and dampens shocks and vibrations. For example, but not limited to, bumpers 106 may be made of rubber. In various embodiments, bumpers 106 may be used on the edges of PCB board 104. Thus, it is not necessary that bumpers 106 be located at each of the corners.

Second PCB board 116 can be rigidly mounted to base 108. External connector 120 can be mounted on second PCB board 116. In various embodiments, external connector 120 is provided for removably connecting removable data storage device 100 to computing devices, which may then read or write data to memory device 102. Thus, as used herein, the term computing device may be any appropriate device that may read or write data to a memory device including, but not limited to, personal computers, lap top computers, personal digital assistants (PDAs), video recorders, data recorders, and audio recorders. In some embodiments, the external connector can be, for example, but not limited to, a multiple point contact connector. In some embodiments, the external connector 120 can be, for example, but not limited to, a multiple-pin connector. In various embodiments, power may be provided to first PCB board 104, second PCB board 116 and memory device 102 through external connector 120.

First PCB board 104 and second PCB board 116 communicate via flexible connector 118. Thus, memory device 102 is able to communicate with external connector 120. Specifically, memory device 102 communicates with first PCB board 104 via connector 122. First PCB board 104 communicates with second PCB board 116 via flexible connector 118. Second PCB board 116 communicates with external devices via external connector 120.

The use of flexible connector 118 allows for movement of first PCB board 104 relative the rest of removable data storage device 100. Flexible connector 118 can be, for example, but not limited to, a plurality of flexible wires, a flexible cable, or a flexible multi-conductor cable. In various embodiments of applicant's teachings illustrated in FIG. 1B, flexible connector 118 is a flexible multi-conductor cable. In addition, in some embodiments of applicant's teachings, flexible connector 118 is not taut. The use of flexible connector 118 ensures that when any shocks or vibrations are experienced by removable data storage device 100, the resulting movement of second PCB board 116 does not substantially transfer motion to first PCB board 104 as it would if first PCB board 104 and second PCB board 116 were connected through a rigid or taut connection. In addition, the use of flexible connector 118 allows for movement of second PCB board 116 relative to first PCB board 104 without the electrical connection being broken.

In various embodiments according to applicant's teachings, bumpers 106 are not affixed to base 108 or any other portion of removable data storage device 100. As a result, this allows bumpers 106 and anything held by them to move independently of the rest of the removable data storage device 100. Consequently, it is possible for bumpers 106 to cushion first PCB board 104 from shocks and vibrations by allowing the rest of data storage device 100 to move with the shocks and vibrations while keeping first PCB board 104 (and consequently memory device 102) from moving in a violent manner.

In some embodiments, the movement of bumpers 106 is constrained by a first plurality of tabs 110 on base 106, a second plurality of tabs 114 on cover 112, by base 108, and by the sidewalls of cover 112. In the embodiments illustrated in FIGS. 1A to 1E, the first plurality of tabs 110 comprises four tabs, one at each corner of PCB board 110. As can bee seen from FIGS. 1B, 1C and 1D, each of the plurality of tabs 110 is perpendicular to the direction X. Tabs 110 constrain or limit the amount of motion of that bumpers 106 may experience in the direction X. Similarly, the inner surface of base 108 as well as the second plurality of tabs 114, which are located on cover 112, constrain or limit the amount of motion that bumpers 106 may experience in the direction Y. Finally, sidewalls 112 constrain or limit the amount of motion that bumpers 106 may experience in the direction Z. Directions X, Y and Z are orthogonal.

In some embodiments, bumpers 106 physically isolate the PCB board 104 and memory device 102 from the rest of data storage device 100. As used herein, the term to “physically isolate” refers to a lack of contact between the interior of data storage device 100 and either of PCB board 104 or memory device 102. It not necessarily used to imply that there is a physical barrier that substantially surrounds PCB board 104 and memory device 102, although it is not intended to exclude such embodiments.

In the embodiments illustrated in FIGS. 1A to 1E, bumpers 106 physically isolate PCB board 104 from the rest of data storage device 100 (other than memory device 102) by suspending it away from base 108. The only contact between PCB board 104 and other portions data storage device 100 (other than memory device 102) is through bumpers 106 and flexible connector 118. Similarly, in some embodiments memory device 102 does not contact any other portion of data storage device other than PCB board 104. However, it is not intended to exclude embodiments in which bumpers 106 contact memory device 102. It is not intended to exclude embodiments in which flexible connector 118 is directly coupled to memory device 102.

Given that memory device 102 is affixed to PCB board 104, memory device 102 is also suspended away from other parts of data storage device 100. Contact between memory device 102 and the interior of cover 112 is prevented by ensuring that the height at which PCB board 104 is suspended is not sufficient to cause contact between the portion of memory device 102 furthest away from PCB board 104 and the interior of cover 112. In addition, as described above, bumpers 106 interact with various sidewalls and tabs to prevent contact between memory device 102 and the interior of data storage device 100 as well as between PCB board 104 and the interior of data storage device 100.

It should be noted that in other embodiments, different combinations of sidewalls and tabs are used to hold bumpers 106 in place. Moreover, it is not intended to exclude the provision of additional padding or dampening of vibrations through the placement of shock absorbing material between memory device 102 and any of the sidewalls of cover 112 or between memory device 102 and the top of cover 112, or between first PCB board 104 and base 108, or between first PCB board 104 and any of the sidewalls of cover 112 or between first PCB board 104 and second PCB board 116. It should be understood that although bumpers 106 are shown having a height less than that of interior of removable data storage device 100, it is not intended to exclude the possibility of bumpers 106 extending the entire height of removable data storage device 100.

Bumpers 106 prevent shocks and vibrations experienced by removable data storage device 100 from reaching first PCB board 104. Given that memory device 102 is rigidly affixed to first PCB board 104, by preventing excessive shocks and vibrations form reaching PCB board 104, bumpers 106 effectively protect memory device 102, from shocks and vibrations as well. If memory device 102 is an electromechanical device such as a HDD then memory device 102 will in general be susceptible to damage by shocks or vibrations. However, since bumpers 106 prevent shocks and vibrations from reaching memory device 102, it would be unlikely for memory device 102 to be damaged even when vibrations and shocks may be experience by the overall removable data storage device 100.

In various embodiments of applicant's teachings external housing 124 of removable data storage device 100 is made of a strong durable material. For example, external housing 124 may be made of, but is not limited to, steal or aluminum. In various embodiments, external housing 124 may be reinforced to withstand the effects of explosions or direct hits from projectiles, which may include but are not limited to, bullets.

In various embodiments of applicant's teachings, removable data storage apparatus 100 is portable and able to survive the application of external forces as a result of shocks, vibrations, turbulence, hits, drops, falls, knocks and bumps. As used herein, the term survive refers not only to the preservation of the physical integrity of apparatus 100 but also the preservation of the data stored on memory device 102. External housing 124 prevents damage to the internal components of data recording apparatus 100 when a strong force is externally applied to data recording apparatus 100, as when for example, but not limited to, data recording apparatus 100 is dropped and falls to the ground. In addition, as described above, bumpers 106 prevent excessive shocks and vibrations from reaching memory device 102.

While the applicant's teachings are described in conjunction with various embodiments, it is not intended that the applicant's teachings be limited to such embodiments. On the contrary, the applicant's teachings encompass various alternatives, modifications, and equivalents, as will be appreciated by those of skill in the art.

I claim:

1. A removable data storage device comprising:
an external connector to removably connect the data storage device to a computing device;
a memory device mounted on a first printed circuit board;
a flexible connector for providing an electrical connection between the memory device and the external connector;
a housing for enclosing the memory device; and
a plurality of bumpers for physically isolating the memory device and printed circuit board from the housing, each bumper shaped to securely receive at least one edge of the printed circuit board.

2. The removable data storage device of claim 1, wherein the memory device is electrically coupled to the first printed circuit board and a first end of the flexible connector is electrically coupled to the first printed circuit board to provide the electrical connection between the memory device and the external connector.

3. The data storage device of claim 2, wherein the memory device is rigidly mounted on the printed circuit board.

4. The removable data storage device of claim 2, further comprising a second printed circuit board, the second printed circuit board mounted in the housing, so that the external connector is mounted on and electrically coupled to the second printed circuit board, and a second end of the flexible connector is coupled to the second printed circuit board in order to provide the electrical connection between the memory device and the external connector.

5. The removable data storage device of claim 1, further comprising a plurality of tabs affixed to the housing, so that each tab abuts a bumper in order to prevent movement of the bumper.

6. The removable data storage device of claim 1, wherein each bumper is made of a shock absorbing material.

7. The removable data storage device of claim 6, wherein the shock absorbing material is rubber.

8. The removable data storage device of claim 1, wherein the external connector is a multiple point contact connector.

9. The removable data storage device of claim 1, wherein the external connector is a multiple-pin contact connector.

10. The removable data storage device of claim 1, wherein power is provided to the memory device through the external connector.

11. The removable data storage device of claim 1, wherein the printed circuit board has a rectangular shape and the plurality of bumpers comprises four corner bumpers, each corner bumper shaped to receive a corner of the printed circuit board.

12. A method of protecting a memory device form shocks and vibrations, the method comprising:
(a) providing an external connector for coupling the data storage device to a computing device;
(b) providing a flexible connector for providing an electrical connection between the memory device and the external connector;
(c) mounting the memory device on a first printed circuit board;
(d) providing a housing for enclosing the memory device; and
(e) providing a plurality of bumpers for physically isolating the memory device and printed circuit board from the housing, each bumper shaped to securely receive at least one edge of the printed circuit board.

13. The method of claim 12, further comprising:
(f) electrically coupling the memory device to the first printed circuit board,
so that (b) further comprises electrically coupling the flexible connector to the first printed circuit board to provide the electrical connection between the memory device and the external connector.

14. The method of claim 12, wherein (c) comprises rigidly mounting the memory device on the printed circuit board.

15. The method of claim 13, further comprising:
(g) providing a second printed circuit board;
(h) mounting the second circuit board to the housing; and
(i) mounting and electrically coupling the external connector to the second printed circuit board,
so that (b) further comprises electrically coupling the flexible connector to the second printed circuit board in order to provide the electrical connection between the memory device and the external connector.

16. The method of claim 12, further comprising providing a plurality of tabs affixed to the housing, so that each tab abuts a bumper in order to prevent movement of the bumper.

17. The method of claim 12, wherein each bumper is made of a shock absorbing material.

18. The method of claim 17, wherein the shock absorbing material is rubber.

19. The method of claim 12, wherein the external connector is a multiple point contact connector.

20. The method of claim 12, wherein the external connector is a multiple-pin contact connector.

21. The method of claim 12, further comprising providing power to the memory device through the external connector.

22. The method of claim 12, wherein the printed circuit board has a rectangular shape and the plurality of bumpers comprises four corner bumpers, each corner bumper shaped to receive a corner of the printed circuit board.
